(19) United States
(12) Patent Application Publication
(10) Pub. No.: US 2024/0023456 A1
(43) Pub. Date: Jan. 18, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 17/887,530

(22) Filed: Aug. 15, 2022

(30) Foreign Application Priority Data
Jul. 13, 2022 (TW) 111126286

(51) Int. Cl. H01L 43/12; G11C 11/16; H01L 43/08; H01L 27/22; H01L 43/02

(52) U.S. Cl. CPC H01L 43/12; G11C 11/161; H01L 43/08; H01L 27/222; H01L 43/02

(57) ABSTRACT

A method for fabricating semiconductor device includes the steps of first forming a spin orbit torque (SOT) layer on a substrate, forming a magnetic tunneling junction (MTJ) stack on the SOT layer, performing a first etching process to remove part of the MTJ stack, and then performing a second etching process to remove part of the MTJ stack for forming a MTJ.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating semiconductor device includes the steps of first forming a spin orbit torque (SOT) layer on a substrate, forming a magnetic tunneling junction (MTJ) stack on the SOT layer, performing a first etching process to remove part of the MTJ stack, and then performing a second etching process to remove part of the MTJ stack for forming a MTJ.

According to another aspect of the present invention, a semiconductor device includes a spin orbit torque (SOT) layer on a substrate and a magnetic tunneling junction (MTJ) on the SOT layer. Preferably, a sidewall of the MTJ includes a first slope and a second slope and the first slope is less than the second slope.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a MRAM device according to an embodiment of the present invention.

### DETAILED DESCRIPTION

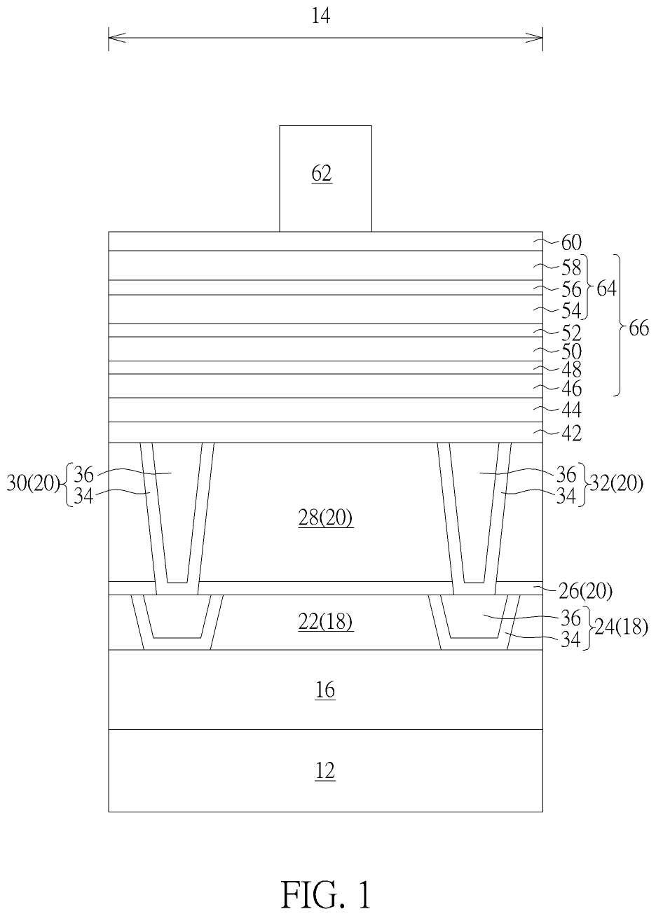

Referring to FIGS. 1-5, FIGS. 1-5 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MTJ region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a selective bottom electrode 42, a spin orbit torque (SOT) layer 44, a MTJ stack 66, a cap layer 60, and a patterned mask 62 are formed on the metal interconnect structure 20. In this embodiment, the formation of the MTJ stack 66 could be accomplished by sequentially depositing a free layer 46, a barrier layer 48, a reference layer 50, a spacer 52, and a pinned layer 64 on the SOT layer 44. Preferably, the free layer 46 could be made of ferromagnetic material including but not limited to for example iron, cobalt, nickel, or alloys thereof such as cobalt-iron-boron (CoFeB), in which the magnetized direction of the free layer 46 could be altered freely depending on the influence of outside magnetic field. The barrier layer 48 could be made of insulating material including but not limited to for example oxides such as aluminum oxide (AlOₓ) or magnesium oxide (MgO).

The reference layer 50 is disposed between the barrier layer 48 and the spacer 52, in which the reference layer 50 could be made of ferromagnetic material including but not limited to for example iron, cobalt, nickel, or alloys thereof such as cobalt-iron-boron (CoFeB). The spacer 52 could be a non-magnetic layer made of non-magnetic material including but not limited to for example ruthenium (Ru), iridium (Ir), rhodium (Rh), or combination thereof.

The pinned layer 64 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 64 is formed to fix or limit the direction of magnetic moment of adjacent layers. Specifically, the pinned layer 64 further includes a bottom synthetic antiferromagnetic (SAF) layer 54, a coupling layer 56, and a top SAF layer 58, in which the bottom SAF layer 54 and the top SAF layer 58 could include same or different materials while both layers 54, 58 could include ferromagnetic material such as cobalt (Co), nickel (Ni), platinum (Pt), palladium (Pd), or combination thereof. The coupling layer 56 may also include materials to provide mechanical and/or crystalline structural support for the bottom SAF layer 54 and the top SAF layer 58. Preferably, the coupling layer 56 includes material that aides in this coupling including but not limited to ruthenium (Ru), tantalum (Ta), gadolinium (Gd), platinum (Pt), hafnium (Hf), or combination thereof.

Moreover, the selective bottom electrode 42 could include conductive material such as but not limited to for example Ta, TaN, Pt, Cu, Au, Al, or combination thereof, the SOT layer 44 is serving as a channel for the MRAM device as the SOT layer 44 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ru, and the hard mask 62 preferably includes conductive or dielectric material such as tantalum (Ta), tantalum nitride (TaN), titanium (Ti), titanium nitride (TiN), platinum (Pt), copper (Cu), gold (Au), aluminum (Al), or combination thereof.

It should be noted that in contrast to conventional SOT layer 44 not including atoms or dopants other than metal, it would be desirable to implant nitrogen atoms and/or oxygen atoms into the SOT layer 44 in this embodiment through ion implantation process so that the SOT layer 44 formed would include nitrogen and/or oxygen atoms. According to an embodiment of the present invention, the SOT layer 44 could be made of metal nitride or metal oxide. For example, if the original SOT layer 44 were made of tungsten (W), the SOT layer 44 after being implanted with dopants such as nitrogen or oxygen would be made of tungsten nitride (WN) or tungsten oxide (WO). If the original SOT layer 44 were made of platinum (Pt), the SOT layer 44 after being implanted with nitrogen or oxygen would then be made of platinum nitride (PtN) or platinum oxide (PtO), which are all within the scope of the present invention. By implanting dopants such as nitrogen or oxygen into the SOT layer 44, it would be desirable to create a clearer endpoint so that etching process could be stopped on the SOT layer 44 during patterning of MTJ stack 66 for forming MTJ in the later process thereby preventing over loss of SOT layer 44.

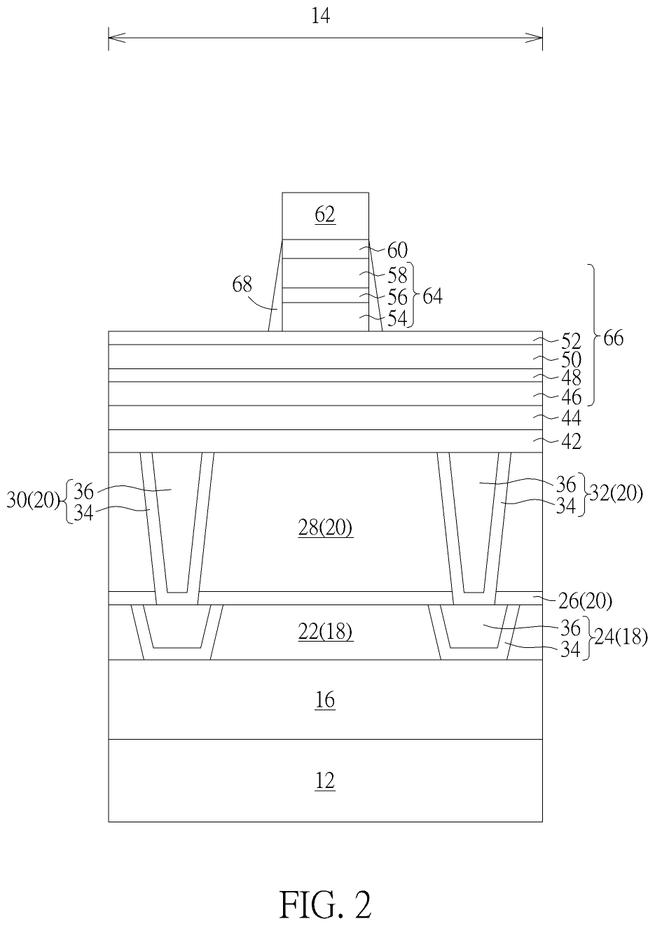

Next, as shown in FIG. 2, an etching process such as an ion beam etching (IBE) process is conducted by using the patterned hard mask 62 as mask to remove part of the cap layer 60 and part of the pinned layer 64 including the top SAF layer 58, part of the coupling layer 56, and part of the bottom SAF layer 54 for exposing the top surface of the spacer 52 underneath. It should be noted that as the IBE process is conducted at this stage to pattern the pinned layer 64, residue 68 made of metallic ions is also formed on the sidewalls of the pinned layer 64 at the same time.

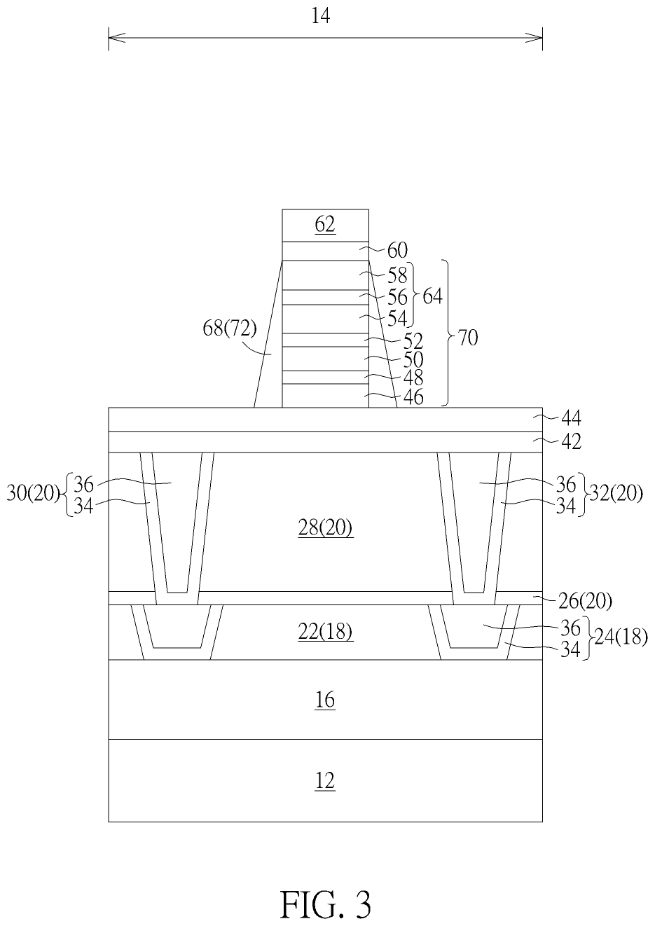

Next, as shown in FIG. 3, another etching process such as a reactive ion etching (ME) process is conducted by using the patterned mask 62 as mask to remove part of the un-patterned MTJ stack 66 including part of the spacer 52, part of the reference layer 50, part of the barrier layer 48, and part of the free layer 46 for forming a MTJ 70 and expose the top surface of the SOT layer 44. It should be noted that when the MTJ stack 66 is patterned through ME process at this stage, another residue 72 is also formed on the sidewalls of the MTJ 70, in which the residue 72 and the residue 68 formed previously in FIG. 2 could be made of same or different materials and the two residues 68 and 72 could unite to form a single residue.

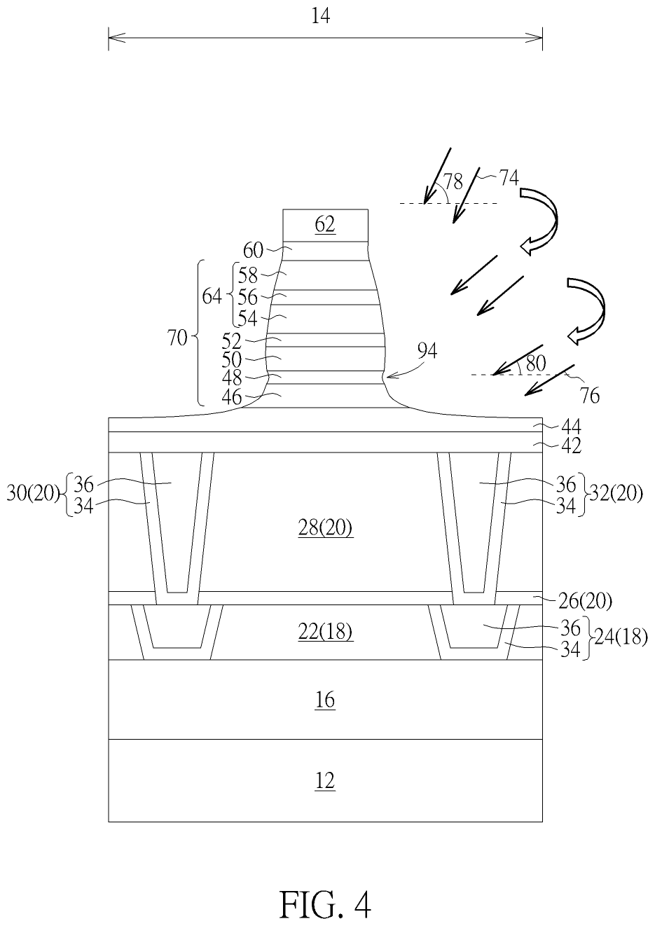

Next, as shown in FIG. 4, a trimming process is conducted to remove the residue 68 and the residue 72, in which the trimming process could include a two stage trimming processes 74, 76 each accomplished by a IBE process to remove the residues 68, 72. Specifically, the first stage of the trimming process 74 involves removing the restudies 68, 72 at a first angle 78 within a first time or duration while the second stage of the trimming process 76 involves removing the remaining residues 68, 72 at a second angle 80 within a second duration, in which the first angle 78 if measured according to a surface parallel to the surface of the substrate 12 is preferably greater than the second angle 80 that is also measured based on a surface parallel to the surface of the substrate 12 and the first duration is less than the second duration.

According to a preferred embodiment of the present invention, the first stage of the trimming process 74 is conducted at a bigger first angle 78 such as 40-60 degrees within a shorter first duration to remove the restudies 68, 72 and the second stage of the trimming process 76 is conducted at a smaller second angle 80 such as 0-20 degrees within a longer second duration to remove the remaining residues 68, 72. It should be noted that even though all of the residues 68, 72 were preferably removed to expose the sidewalls of the MTJ 70 after the trimming processes 74, 76 are completed, under certain circumstances some residues 68, 72 may still remain on sidewalls of the MTJ 70 and to emphasize the sidewall profile of the MTJ 70 after the trimming processes, residues remained on sidewalls of the MTJ 70 are omitted in FIG. 4.

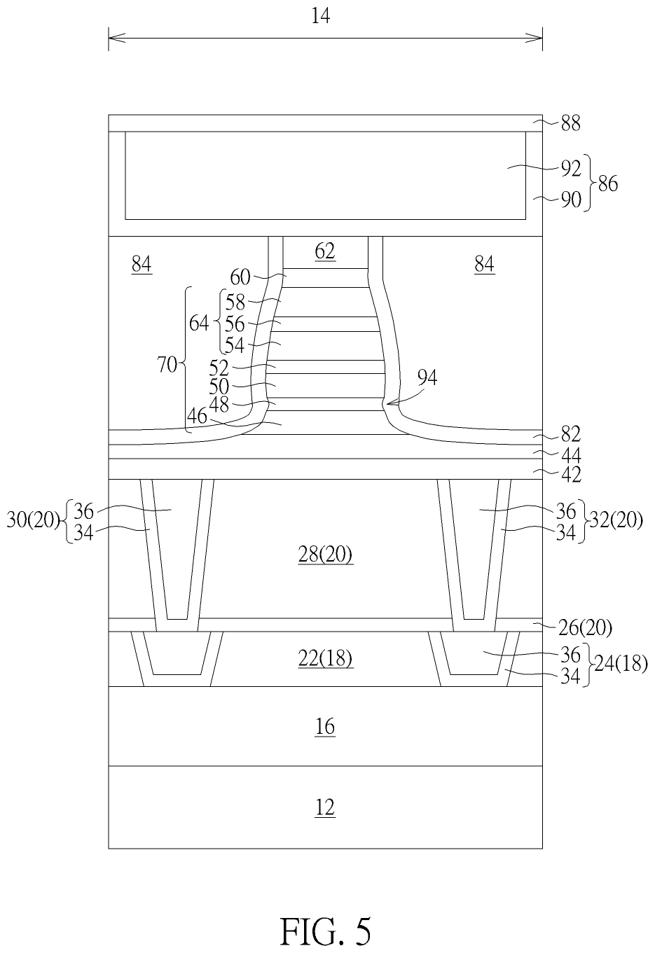

Next, as shown in FIG. 5, a cap layer 82 and an IMD layer 84 are formed on the MTJ 70, and then a planarizing process such as chemical mechanical polishing (CMP) process is conducted to remove part of the IMD layer 84. In this embodiment, the cap layer 82 could include nitrogen doped carbide (NDC), silicon nitride, silicon carbon nitride (SiCN), or combination thereof and the IMD layer 84 preferably includes an ultra low-k (ULK) dielectric layer including but not limited to for example porous material or silicon oxycarbide (SiOC) or carbon doped silicon oxide (SiOCH).

Next, one or more photo-etching process is conducted to remove part of the IMD layer 84 to form a contact hole (not shown), conductive materials are deposited into the contact hole, a planarizing process such as CMP is conducted to form a metal interconnection 86 connecting the hard mask 62 underneath, and another stop layer 88 is formed on the surface of the metal interconnection 86. Similar to the metal interconnections 24 formed previously, the metal interconnection 86 could be formed in the IMD layer 84 through a single damascene or dual damascene process. For instance, the metal interconnection 86 could further include a barrier layer 90 and a metal layer 92, in which the barrier layer 90 could be selected from the group consisting of titanium (Ti), titanium nitride (TiN), tantalum (Ta), and tantalum nitride (TaN) and the metal layer 92 could be selected from the group consisting of tungsten (W), copper (Cu), aluminum (Al), titanium aluminide (TiAl), and cobalt tungsten phosphide (CoWP). Moreover, the metal layer 92 in the metal interconnection 86 preferably includes copper and the stop layer 88 could include nitrogen doped carbide (NDC), silicon nitride, silicon carbon nitride (SiCN), or combination thereof. This completes the fabrication of a semiconductor device according to an embodiment of the present invention.

Referring again to FIG. 5, FIG. 5 further illustrates a structural view of a MRAM device according to an embodiment of the present invention. As shown in FIG. 5, the semiconductor device includes a selective bottom electrode 42 disposed on the substrate 12, a SOT layer 44 disposed on the bottom electrode 42 or substrate 12, a MTJ 70 disposed on the SOT layer 44, a cap layer 60 disposed on the MTJ 70, and a hard mask 62 dispose don the cap layer 60. Preferably, the MTJ 70 from bottom to top includes a free layer 46, a barrier layer 48, a reference layer 50, a spacer 52, and a pinned layer 64, in which the pinned layer 64 further includes a bottom SAF layer 54, a coupling layer 56, and a top SAF layer 58.

Specifically, the sidewalls of the MTJ 70 after being treated with the two trimming processes 74, 76 at two different angles preferably include at least two different slopes such as a first slope and a second slope, in which a sidewall of the free layer 46 preferably includes the first slope while a sidewall of the pinned layer 64 includes the second slope. According to a preferred embodiment of the present invention, since the first stage of the trimming process 74 is conducted at a bigger first angle 78 such as 40-60 degrees within a shorter first duration to remove the restudies 68, 72 and the second stage of the trimming process 76 is conducted at a smaller second angle 80 such as 0-20 degrees within a longer second duration to remove the remaining residues 68, 72, the sidewalls of the pinned layer 64 situated on a more upper level would be converted to slightly steeper sidewalls having greater first slope value whereas the sidewalls of the free layer 46 on lower level would be converted to slightly flatter sidewalls having smaller second slope value.

Moreover, the sidewalls of the barrier layer 48 between the free layer 46 and the reference layer 50 are also slightly over-etched during the trimming process to form recesses 94 or indentations slightly concave inward and at the same time, the top surface of the SOT layer 44 adjacent to two sides of the MTJ 70 could also be slightly lower than the top surface of the SOT layer 44 directly under the MTJ 70 as a result of the aforementioned multiple etching processes, which are all within the scope of the present invention.

Overall, the present invention proposes an approach of patterning the MTJ stack for forming MTJ through different etching processes, which first conducts a first IBE process to pattern part of the pinned layer, conducts a RIE process to pattern the spacer, the reference layer, the barrier layer, and the free layer to form MTJ while using the nitrogen atoms or oxygen atoms implanted in the SOT layer to stop the etching process on the surface of the SOT layer, and then finally conducts a two stage IBE or trimming processes to remove residues from sidewalls of the MTJ so that the sidewalls of the final MTJ would demonstrate different slopes. By using the aforementioned mixed recipe of etching processes to pattern the MTJ stack for forming MTJ, it would be desirable to minimize damages to the SOT layer as a result of unclear endpoint caused by only using a single etching process for forming the MTJ.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
forming a spin orbit torque (SOT) layer on a substrate;
forming a magnetic tunneling junction (MTJ) stack on the SOT layer;
performing a first etching process to remove part of the MTJ stack; and
performing a second etching process to remove part of the MTJ stack for forming a MTJ.

2. The method of claim 1, further comprising:
forming a free layer on the SOT layer;
forming a barrier layer on the free layer;
forming a pinned layer on the barrier layer;
performing the first etching process to remove the pinned layer; and
performing the second etching process to remove the barrier layer and the free layer.

3. The method of claim 1, further comprising:
performing the first etching process to form a first residue adjacent to the MTJ stack;
performing the second etching process to form a second residue adjacent to the MTJ stack; and
performing a trimming process to remove the first residue and the second residue.

4. The method of claim 3, wherein the trimming process comprises:
performing a first trimming process to remove the first residue and the second residue at a first angle within a first duration; and
performing a second trimming process to remove the first residue and the second residue at a second angle within a second duration.

5. The method of claim 4, wherein the first angle is less than the second angle.

6. The method of claim 4, wherein the first duration is less than the second duration.

7. The method of claim 3, wherein the trimming process comprises an ion beam etching (IBE) process.

8. The method of claim 1, wherein the first etching process comprises an ion beam etching (IBE) process.

9. The method of claim 1, wherein the second etching process comprises a reactive ion etching (RIE) process.

10. The method of claim 1, wherein the SOT layer comprises nitrogen.

11. The method of claim 1, wherein the SOT layer comprises oxygen.

12. A semiconductor device, comprising:
a spin orbit torque (SOT) layer on a substrate; and
a magnetic tunneling junction (MTJ) on the SOT layer, wherein a sidewall of the MTJ comprises a first slope and a second slope.

13. The semiconductor device of claim 12, wherein the MTJ comprises:
a free layer on the SOT layer;
a barrier layer on the free layer; and
a pinned layer on the barrier layer.

14. The semiconductor device of claim 13, wherein the free layer comprises the first slope and the pinned layer comprises the second slope.

15. The semiconductor device of claim 14, wherein the first slope is less than the second slope.

16. The semiconductor device of claim 13, wherein a sidewall of barrier layer comprises a recess.

17. The semiconductor device of claim 12, wherein a top surface of the SOT layer adjacent to the MTJ is lower than a top surface of the SOT layer under the MTJ.

18. The semiconductor device of claim 12, wherein the SOT layer comprises nitrogen.

19. The semiconductor device of claim 12, wherein the SOT layer comprises oxygen.
